(19) United States
(12) Patent Application Publication
(10) Pub. No.: US 2026/0371506 A1
(43) Pub. Date: Nov. 19, 2026

(54) Electronic Devices with Hinges

(71) Applicant: Apple Inc., Cupertino, CA (US)

(72) Inventors: Tatsuya Sano, San Jose, CA (US); Bradley J. Hamel, Portola Valley, CA (US); Scott J. Krahn, Cupertino, CA (US); Peng Peng, Milpitas, CA (US); Colin M. Wang, Cupertino, CA (US); Yu-Chieh Lee, New Taipei City (TW); Michael B. Wittenberg, San Francisco, CA (US); Macey E. Dade, Burlingame, CA (US)

(21) Appl. No.: 19/665,970

(22) Filed: May 1, 2026

Related U.S. Application Data
(60) Provisional application No. 63/805,215, filed on May 13, 2025.

(51) Int. Cl. H05K 5/02

(52) U.S. Cl. CPC H05K 5/0226

(57) ABSTRACT

An electronic device may include a housing having first and second housing portions coupled by a hinge. A flexible display may be mounted to the housing and may include first and second portions that fold relative to one another along a bend axis. Retractable support structures may be movable between a first position in which the retractable support structures support the flexible display and a second position in which the retractable support structures are retracted into the housing. The retractable support structures may transition from the first position to the second position when the angle between the first and second portions of the display drops below a threshold angle (e.g., an angle less than 135°). The hinge may include a torque module that has two sets of springs and three cams. Linkages may include portions with non-circular curvature to provide additional clearance between the flexible display and the housing.

This application claims the benefit of U.S. provisional patent application No. 63/805,215, filed May 13, 2025, which is hereby incorporated by reference herein in its entirety.

### FIELD

This relates generally to electronic devices and, more particularly, to electronic devices with displays.

### BACKGROUND

Electronic devices often have displays. Portability may be a concern for some devices, which tends to limit available real estate for displays.

### SUMMARY

An electronic device may include a flexible display having first and second display portions that rotate relative to one another about a bend axis. The flexible display may be mounted to a foldable housing having first and second housing portions coupled by a hinge that overlaps the bend axis. The flexible display may be operable in a flat (e.g., open) state and a folded (e.g., closed) state. The flexible display may also be operable at intermediate states between the open and closed states. For example, one or more torque modules in the hinge may be used to maintain a desired angle between the first and second housing portions (e.g., so that the display can be used in a laptop-style position in which the two display portions are separated by an angle of 90°, 100°, 95°, and/or any other suitable angle).

Retractable support structures in the hinge region may be movable between a first position in which the retractable support structures support the flexible display and a second position in which the retractable support structures retract into the housing (e.g., to accommodate a teardrop shape of the flexible display when folded closed). The retractable support structures may transition from the first position to the second position when the angle between the first and second portions of the display drops below a threshold angle (e.g., an angle less than 135°, an angle less than 115°, an angle less than 100°, an angle less than 90°, or any other suitable threshold angle).

The hinge may include a torque module for maintaining a desired angle between the two portions of the display. The torque module may include two sets of springs and three cams. In some arrangements, the torque module may include one set of springs, two cams, and supplemental springs that are laterally offset from the bend axis to provide additional torque at intermediate angles between the two portions of the display.

A hinge may include a set of linkages such as linkages that rotate relative to a torque module and linkages that rotate relative to a center support structure. Some of the linkages may slide within slots behind a center support structure during opening and closing of the device. If desired, these linkages may include portions with non-circular curvature to provide additional clearance between the display and the housing in the folded state.

### BRIEF DESCRIPTION OF THE DRAWINGS

FIG. 1 is a schematic diagram of an illustrative electronic device in accordance with some embodiments.

FIG. 2 is a perspective view of an illustrative electronic device with a display in accordance with some embodiments.

FIG. 3 is a side view of an illustrative electronic device having a hinge in accordance with some embodiments.

FIG. 4 is a side view of an illustrative electronic device having a hinge with torque modules and retractable support structures in accordance with some embodiments.

FIG. 5 is a side view of the electronic device of FIG. 4 in a folded state in accordance with some embodiments.

FIG. 6 is a perspective view of an illustrative center support structure with one or more recesses for constraining motion of a retractable support structure in accordance with some embodiments.

FIG. 7 is a side view of an illustrative hinge showing how motion of a retractable support structure may be constrained by a center support structure in accordance with some embodiments.

FIG. 8 is a top view of an illustrative torque module that includes two sets of springs and three cams in accordance with some embodiments.

FIG. 9 is a perspective view of an illustrative torque module that includes a set of springs, two cams, and supplemental springs that are offset from a bend axis in accordance with some embodiments.

FIG. 10 is a side view of an illustrative hinge having linkages with non-circular portions that rotate relative to a center support structure in accordance with some embodiments.

### DETAILED DESCRIPTION

Electronic devices may be provided with displays. Displays may be used for displaying images for users. Displays may be formed from arrays of light-emitting diode pixels or other pixels. For example, a device may have an organic light-emitting diode display or a display formed from an array of micro-light-emitting diodes (e.g., diodes formed from crystalline semiconductor dies).

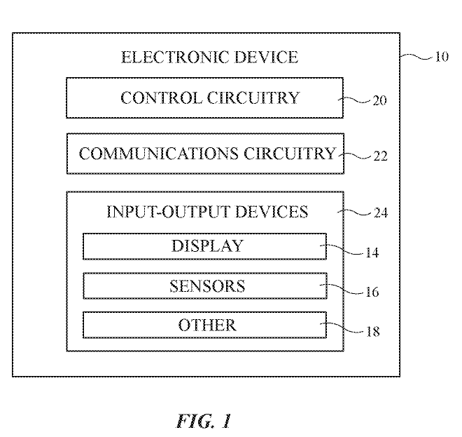

A schematic diagram of an illustrative electronic device having a display is shown in FIG. 1. Device 10 may be a cellular telephone, tablet computer, laptop computer, wristwatch device or other wearable device, a television, a stand-alone computer display or other monitor, a computer display with an embedded computer (e.g., a desktop computer), a system embedded in a vehicle, kiosk, or other embedded electronic device, a media player, or other electronic equipment. Configurations in which device 10 is a cellular telephone, tablet computer, or other portable electronic device may sometimes be described herein as an example. This is illustrative. Device 10 may, in general, be any suitable electronic device with a display.

Device 10 may include control circuitry 20. Control circuitry 20 may include storage and processing circuitry for supporting the operation of device 10. The storage and processing circuitry may include storage such as nonvolatile memory (e.g., flash memory or other electrically-programmable-read-only memory configured to form a solid state drive), volatile memory (e.g., static or dynamic random-access-memory), etc. Processing circuitry in control circuitry 20 may be used to gather input from sensors and other input devices and may be used to control output devices. The processing circuitry may be based on one or more microprocessors, microcontrollers, digital signal processors, baseband processors and other wireless communications circuits, power management units, audio chips, application specific integrated circuits, etc. During operation, control circuitry 20 may use a display and other output devices in providing a user with visual output and other output.

To support communications between device 10 and external equipment, control circuitry 20 may communicate using communications circuitry 22. Circuitry 22 may include antennas, radio-frequency transceiver circuitry (wireless transceiver circuitry), and other wireless communications circuitry and/or wired communications circuitry. Circuitry 22, which may sometimes be referred to as control circuitry and/or control and communications circuitry, may support bidirectional wireless communications between device 10 and external equipment over a wireless link (e.g., circuitry 22 may include radio-frequency transceiver circuitry such as wireless local area network transceiver circuitry configured to support communications over a wireless local area network link, near-field communications transceiver circuitry configured to support communications over a near-field communications link, cellular telephone transceiver circuitry configured to support communications over a cellular telephone link, or transceiver circuitry configured to support communications over any other suitable wired or wireless communications link). Wireless communications may, for example, be supported over a Bluetooth® link, a WiFi® link, a wireless link operating at a frequency between 6 GHz and 300 GHz, a 60 GHz link, or other millimeter wave link, cellular telephone link, wireless local area network link, personal area network communications link, or other wireless communications link. Device 10 may, if desired, include power circuits for transmitting and/or receiving wired and/or wireless power and may include batteries or other energy storage devices. For example, device 10 may include a coil and rectifier to receive wireless power that is provided to circuitry in device 10.

Device 10 may include input-output devices such as devices 24. Input-output devices 24 may be used in gathering user input, in gathering information on the environment surrounding the user, and/or in providing a user with output. Devices 24 may include one or more displays such as display 14. Display 14 may be an organic light-emitting diode display, a liquid crystal display, an electrophoretic display, an electrowetting display, a plasma display, a microelectromechanical systems display, a display having a pixel array formed from crystalline semiconductor light-emitting diode dies (sometimes referred to as microLEDs), and/or other display. Configurations in which display 14 is an organic light-emitting diode display or microLED display are sometimes described herein as an example.

Display 14 may have an array of pixels configured to display images for a user. The pixels may be formed as part of a display panel that is bendable. This allows device 10 to be folded and unfolded about a bend axis. For example, a flexible (bendable) display in device 10 may be folded so that device 10 may be placed in a compact shape for storage and may be unfolded when it is desired to view images on the display.

Sensors 16 in input-output devices 24 may include force sensors (e.g., strain gauges, capacitive force sensors, resistive force sensors, etc.), audio sensors such as microphones, touch and/or proximity sensors such as capacitive sensors (e.g., a two-dimensional capacitive touch sensor integrated into display 14, a two-dimensional capacitive touch sensor overlapping display 14, and/or a touch sensor that forms a button, trackpad, or other input device not associated with a display), and other sensors. If desired, sensors 16 may include optical sensors such as optical sensors that emit and detect light, ultrasonic sensors, optical touch sensors, optical proximity sensors, and/or other touch sensors and/or proximity sensors, monochromatic and color ambient light sensors, image sensors, fingerprint sensors, temperature sensors, sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices that capture three-dimensional images), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 16 and/or other input-output devices to gather user input. For example, buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.

If desired, electronic device 10 may include additional components (see, e.g., other devices 18 in input-output devices 24). The additional components may include haptic output devices, audio output devices such as speakers, light-emitting diodes for status indicators, light sources such as light-emitting diodes that illuminate portions of a housing and/or display structure, other optical output devices, and/or other circuitry for gathering input and/or providing output. Device 10 may also include a battery or other energy storage device, connector ports for supporting wired communication with ancillary equipment and for receiving wired power, and other circuitry.

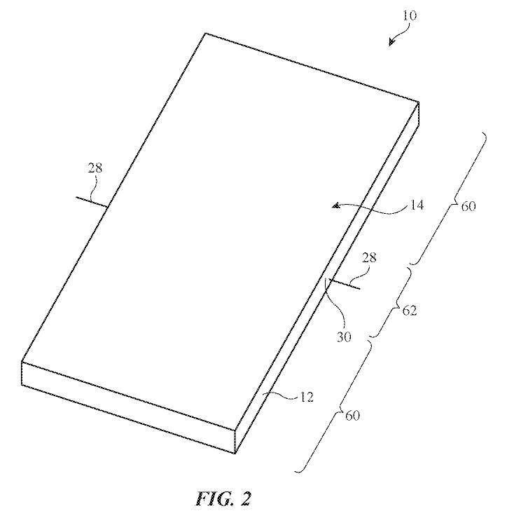

FIG. 2 is a perspective view of electronic device 10 in an illustrative configuration in which device 10 is a portable electronic device such as a cellular telephone or tablet computer. As shown in FIG. 2, device 10 may have a display such as display 14. Display 14 may cover some or all of the front face of device 10. Touch sensor circuitry such as two-dimensional capacitive touch sensor circuitry may be incorporated into display 14.

Display 14 may be mounted in housing 12. Housing 12 may form front and rear housing walls, sidewall structures, and/or internal supporting structures (e.g., a frame, an optional midplate member, etc.) for device 10. Glass structures, transparent polymer structures, and/or other transparent structures that cover display 14 and other portions of device 10 may provide structural support for device 10 and may sometimes be referred to as housing structures. For example, a transparent housing portion such as a glass or polymer housing structure that covers and protects a pixel array in display 14 may serve as a display cover layer for the pixel array while also serving as a housing wall on the front face of device 10. In configurations in which a display cover layer is formed from glass, the display cover layer may sometimes be referred to as a display cover glass or display cover glass layer. The portions of housing 12 on the sidewalls and rear wall of device 10 may be formed from glass or other transparent structures and/or opaque structures. Sidewalls and rear wall structures may be formed as extensions to the front portion of housing 12 (e.g., as integral portions of the display cover layer) and/or may include separate housing wall structures.

Device 10 may be a foldable electronic device that folds along one or more bend axes such as bend axis 28. In the example of FIG. 2, device 10 includes first and second portions 60 joined by bendable portion 62. Portions 60 of device 10 (e.g., portions 60 of display 14 and housing 12, sometimes referred to as the non-bending regions of device 10) may rotate relative to one another about axis 28. As one portion 60 rotates relative to another portion 60 (e.g., during folding and unfolding of device 10), bendable portion 62 of display 14 may bend and flex (e.g., while portions 60 remain flat).

Housing 12 may have flexible structures (e.g., bendable housing wall structures) and/or hinge structures such as hinge 30. Hinge 30 may have a hinge axis aligned with or offset relative to display bend axis 28, depending on the type of hinge used. Bend axis 28 may, for example, be the bend axis around which display 14 bends, whereas hinge 30 may bend about a hinge bend axis. In some arrangements such as teardrop hinge arrangements, the hinge bend axis of hinge 30 may be aligned with display bend axis 28 of display 14. In other arrangements such as constant length hinge arrangements (e.g., a roller hinge), the hinge bend axis may be offset from display bend axis 28. In roller hinge arrangements, device 10 may include one or more translation modules that facilitate translation of display 14 relative to housing 12 that may be needed to accommodate an offset between display bend axis 28 and the hinge bend axis. In teardrop hinge arrangements, hinge 30 may include retractable support structures (sometimes referred to as sink floors) that retract into housing 12 (e.g., into a hinge cover portion of housing 12) to accommodate the teardrop shape (sometimes referred to as a waterdrop shape) of display 14 in bend region 62 when device 10 is folded.

Hinge 30 and/or flexible housing structures that overlap bend axis 28 may allow housing 12 to bend about the hinge bend axis. For example, portion 60 of housing 12 may be located on one side of hinge 30 and another portion 60 of housing 12 may be located on the opposing side of hinge 30. Portions 60 of housing 12 may be configured to rotate relative to one another about hinge 30.

As housing 12 is bent about hinge 30, the flexibility of display 14 allows display 14 to bend about axis 28. In an illustrative configuration, housing 12 and display 14 may bend by 180°. This allows display 14 to be folded over on itself (e.g., such that first and second portions 60 of display 14 face each other). The ability to place device 10 in a folded configuration in this way may help make device 10 compact so that device 10 can be stored efficiently. When it is desired to view images on display 14, device 10 may be unfolded about axis 28 to place device 10 in the unfolded (e.g., flat) configuration of FIG. 2. This allows display 14 to lie flat and allows a user to view flat images on display 14. Device 10 and display 14 may also be operable at intermediate angles between unfolded (e.g., fully flat in which first and second portions 60 are separated by an angle of 180°) and folded closed (e.g., in which first and second portions 60 are separated by an angle of 0°). The ability to fold display 14 onto itself allows device 10 to exhibit an inwardly folding behavior. Display 14 may be sufficiently flexible to allow device 10 to be folded outwardly and/or inwardly, if desired.

Device 10 of FIG. 2 has a rectangular outline (rectangular periphery) with four corners. As shown in FIG. 2, a first pair of parallel edges (e.g., the left and right edges of device 10 in the example of FIG. 2) may be longer than a second pair of parallel edges (e.g., the upper and lower edges of device 10 of FIG. 2) that are oriented at right angles to the first pair of parallel edges. In this type of configuration, housing 12 is elongated along a longitudinal axis that is perpendicular to bend axis 28. Housing 12 may have other shapes, if desired (e.g., shapes in which housing 12 has a longitudinal axis that extends parallel to bend axis 28). With an arrangement of the type shown in FIG. 2, the length of device 10 along its longitudinal axis may be reduced by folding device 10 about axis 28.

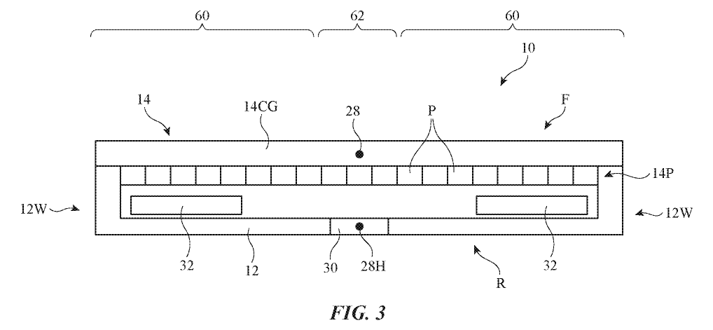

FIG. 3 is a cross-sectional side view of an illustrative foldable electronic device. Device 10 of FIG. 3 may bend about bend axis 28. Bend axis 28 may be aligned with display cover layer 14CG or other structures in device 10. For example, bend axis 28 may pass through a portion of display cover layer 14CG or may be located above or below layer 14CG.

Hinge 30 may bend about one or more hinge axes such as hinge bend axis 28H (sometimes referred to as a hinge axis, a rotational axis, etc.). In arrangements where hinge 30 is a teardrop hinge, hinge bend axis 28H of hinge 30 may be aligned with display bend axis 28 of display 14. In arrangements where hinge 30 is a constant length hinge such as a roller hinge, hinge bend axis 28H may be offset from display bend axis 28. Arrangements in which hinge 30 is a teardrop hinge that accommodates a teardrop shape in display 14 in bend region 62 when device 10 is in a folded state are sometimes described herein as an illustrative example.

As shown in FIG. 3, display 14 includes an array of pixels P forming display panel 14P under an inwardly facing surface of display cover layer 14CG. Display panel 14P may be, for example, a flexible organic light-emitting diode display or a microLED display in which light-emitting pixels are formed on a flexible substrate layer (e.g., a flexible layer of polyimide or a sheet of other flexible polymer). Flexible support layer(s) for display 14 may also be formed from flexible glass, flexible metal, and/or other flexible structures.

Display cover layer 14CG may be formed from polymer, glass, crystalline materials such as sapphire, other materials, and/or combinations of these materials. To enhance flexibility, a portion of layer 14CG that overlaps bend axis 28 may be locally thinned (e.g., this portion may be thinned relative to portions of layer 14CG that do not overlap bend axis 28). The thickness of layer 14CG (e.g., the non-thinned portions of layer 14CG) may be 50-200 microns, 70-150 microns, 100-200 microns, 100-600 microns, at least 100 microns, at least 200 microns, less than 600 microns, less than 400 microns, less than 250 microns, less than 150 microns, less than 100 microns, at least 50 microns, or other suitable thickness.

In the example of FIG. 3, housing 12 has portions that form a rear housing wall on rear face R of device 10 and has portions forming sidewalls 12W of device 10. The rear housing wall of housing 12 may form a support layer for components in device 10. Housing 12 may also have one or more interior supporting layers (e.g., frame structures such as an optional midplate, etc.). These interior supporting layers and the rear housing wall may have first and second portions that are coupled to opposing sides of hinge 30 or may be sufficiently flexible to bend around bend axis 28.

Electrical components 32 may be mounted in the interior of device 10 (e.g., between display 14 and the rear of housing 12. Components 32 may include circuitry of the type shown in FIG. 1 (e.g., control circuitry 20, communications circuitry 22, input-output devices 24, batteries, etc.). Display 14 may be mounted on front face F of device 10. When device 10 is folded about axis 28, display cover layer 14CG, display panel 14P, and the other structures of device 10 that overlap bend axis 28 may flex and bend to accommodate folding.

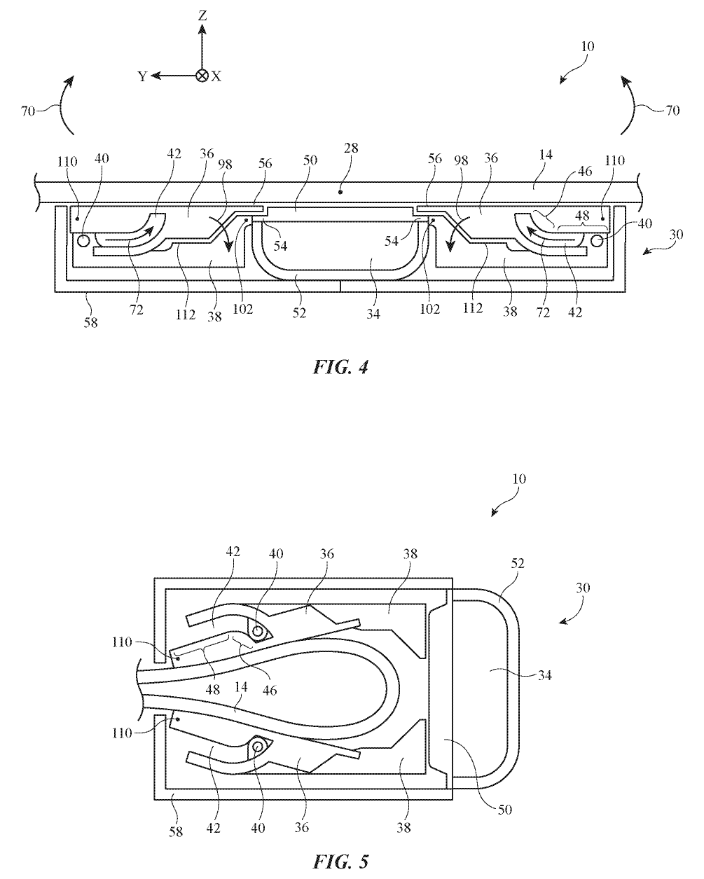

FIG. 4 is a side view of a portion of electronic device 10 showing an illustrative hinge 30 (sometimes referred to as a hinge module) in an open state. As shown in FIG. 4, hinge 30 may include hinge housing structures such as hinge cover 52 interposed between first and second hinge housing members 58. Hinge housing members 58 may be configured to rotate relative to hinge cover 52 as device 10 is opened and closed. Hinge cover 52 may be an elongated housing member that overlaps and extends parallel to bend axis 28. Hinge cover 52 may have a rectangular cross-sectional shape, a circular cross-sectional shape, an oval cross-sectional shape, or any other suitable cross-sectional shape. If desired, hinge cover 52 may be formed from titanium or any other suitable material. Hinge cover 52 and hinge housing members 58 may be part of housing 12 of device 10, if desired.

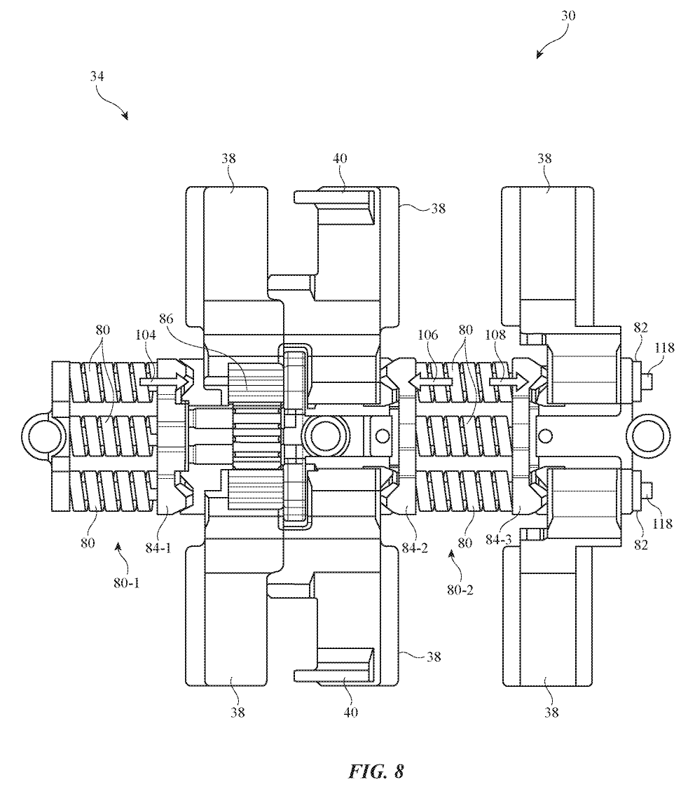

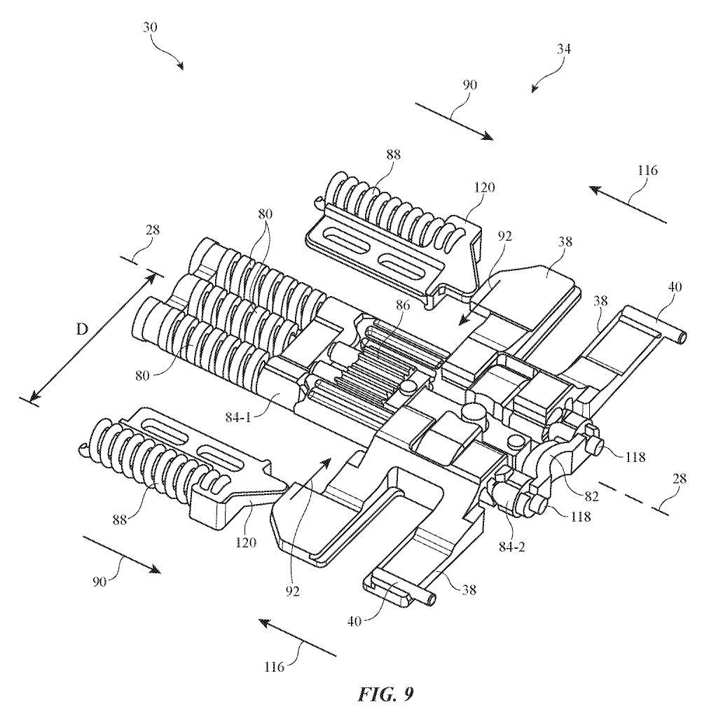

Hinge components may be mounted within hinge cover 52 and hinge housing members 58. For example, one or more torque modules such as torque module 34 may be mounted within hinge cover 52. Torque module 34 may include one or more gears, springs, friction plates, cams, and/or linkages for controlling the folding and unfolding of device 10 and maintaining a desired angle between portions 60 of display 14 (e.g., any angle ranging from 0° at the folded closed position to 180° at the unfolded open position). There may be one, two, three, or more than three torque modules 34 within hinge 30. Narrower products may have limited space and may therefore need to achieve sufficient torque with fewer torque modules 34 (e.g., two torque modules). Illustrative torque modules 34 that may be used in hinge 30 are described in more detail in connection with FIGS. 8 and 9.

Torque module 34 may be coupled to one or more linkages such as linkages 38. Linkages 38 may be coupled to torque module 34 and may be configured to rotate relative to center support structure 50 about respective axes 102. Each torque module 34 may be coupled to two linkages 38, four linkages 38, six linkages 38, and/or any other suitable number of linkages 38. Linkages 38 may be housed within hinge housing members 58.

Hinge cover 52 may be mounted to a center support structure such as center support structure 50. Center support structure 50 (sometimes referred to as a center floor) may be configured to support a portion of display 14 that overlaps and extends parallel to bend axis 28. Center support structure 50 may be formed from metal, amorphous metal (sometimes referred to as metallic glass or glassy metal), ceramic, polymer, glass, and/or any other suitable material. The upper surface of center support structure 50 may be flat and smooth to ensure that display 14 remains flat and smooth (e.g., without creases or wrinkles) along bend axis 28.

To accommodate the teardrop shape of display 14 when device 10 is in the folded state of FIG. 5, hinge 30 may include retractable support structures such as retractable support structures 36 that retract within hinge housing 58 when device 10 is in the folded state. As shown in FIG. 4, first and second retractable support structures 36 (sometimes referred to as sink floors) may be located on opposing sides of center support structure 50 and may be configured to retract downward into hinge housing 58 by rotating in directions 98 about respective axes 110. Linkages 38 may include one or more pins such as pins 40 that slide within recesses such as slots 42 in retractable support structures 36. As device 10 is folded in directions 70, linkages 38 may rotate in directions 70 about axes 102, which in turn causes pins 40 to slide within slots 42 in directions 72. As pins 40 slide within slots 42 in directions 72, retractable support structures 36 may be pulled downward by pins 40 in directions 98. This retraction of support structures 36 into hinge housing 58 widens the gap between support structures 36 to accommodate the teardrop shape of display 14 when device 10 is in the folded state of FIG. 5.

Center support structure 50 may include one or more surfaces (e.g., datums) that constrain motion of retractable support structures 36 when device 10 is in the open state of FIG. 4, as well as when device 10 is positioned at intermediate angles between the open and closed states. For example, center support structure 50 may include one or more recessed portions that form a shelf such as shelf 54 for a portion of support structures 36 such as tabs 56. Tabs 56 on support structures 36 may form mating engagement structures that are received within the recessed portions of center support 50 such as shelf 54. Shelf 54 may help constrain downward motion of retractable support structure 36 along the Z-axis of FIG. 4. If desired, shelf 54 may be surrounded by one or more sidewalls that constrain motion of retractable support structure 36 along the X-axis FIG. 4.

Additional support for retractable support structures 36 within the range of intermediate angles (e.g., when the angle between portions 60 of display 14 is between 179° and 90°) may be provided by linkages 38 (e.g., surfaces 112 of FIG. 4), other linkages in hinge 30 (e.g., swing arms or other linkages), hinge cover 52, and/or any other suitable structure within hinge 30.

It may be desirable to delay retraction of support structures 36 until the angle between the two portions of device 10 (e.g., the angle between a first portion 60 of display 14 on a first side of bend axis 28 and a second portion 60 of display 14 on a second side of bend axis 28) reaches a particular angle. If support structures 36 are retracted at larger angles when display 14 is still being used, display 14 may have insufficient support near hinge 30. For example, when device 10 is in a laptop-style position and the angle between the two non-bending portions 60 of display 14 is 100°, the user may be tapping on a virtual keyboard on display 14 or providing other touch input to a touch sensor in display 14. If care is not taken, a lack of support on the backside of display 14 at these intermediate angles can lead to noticeable deformations in display 14 as the user is typing or otherwise providing touch input on display 14 near hinge 30.

To delay retraction of support structures 36 until the appropriate threshold angle between non-bending portions 60 has been reached, slots 42 may be non-circular (e.g., pins 40 may follow a non-circular path as pins 40 slide within slots 42). For example, outer portions 48 of slots 42 may have no curvature or may otherwise have a larger radius of curvature than inner portions 46 of slots 42. Pins 42 may slide within outer portions 48 of slots 42 as device 10 is rotated from the open (e.g., 180°) position of FIG. 4 to a given threshold angle (e.g., 90°, 80°, 100°, 95°, an angle that is less than 180°, less than 170°, less than 135°, less than 110°, or any other suitable threshold angle). The threshold angle at which retractable support structures 36 begin retracting may be based the location at which slot 42 begins to curve more sharply upward (e.g., the transition point between portion 48 and portion 46 of slot 42). As pin 40 moves from portion 48 to portion 46 of slot 42, pin 40 may begin to pull retractable support structures 36 away from each other and down into housing 58 to provide space for the teardrop portion of display 14, as shown in FIG. 5.

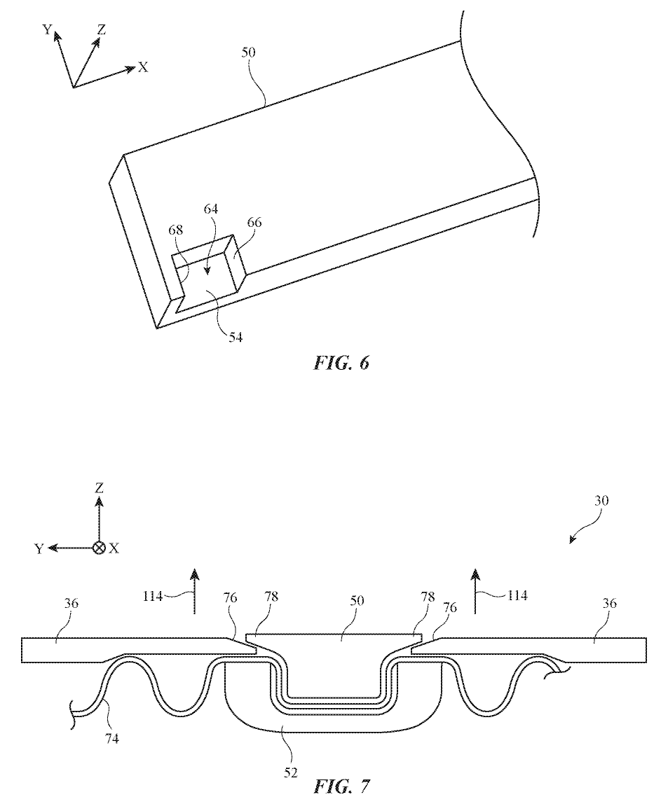

FIG. 6 is a perspective view of center support structure 50 of hinge 30. As shown in FIG. 6, center support structure 50 may include one or more recesses such as recess 64 that forms shelf 54 for tabs 56 of retractable support structures 36 of FIGS. 4 and 5. Center support structure 50 may include sidewalls such as sidewalls 66 and 68 located on opposing sides of shelf 54. Sidewalls 66 and 68 may be configured to constrain motion of retractable support structures 36 along both the positive direction and the negative direction of the X-axis of FIG. 6.

In addition to constraining downward motion along the Z-axis of retractable support structures 36, it may be desirable to constrain upward motion of retractable support structures 36 along the Z-axis. As shown in FIG. 7, a flexible printed circuit such as flexible printed circuit 74 may pass through hinge 30. If care is not taken, the bends in flexible printed circuit 74 may press upwards on retractable support structures 36 in direction 114. To prevent retractable support structures 36 from pushing upwards on display 14, retractable support structures 36 may include tapered edge portions 76 that are interposed between hinge cover 52 and center support structure 50. Tapered edge portions 76 may have a tapered thickness with an upper surface that slopes downward as it approaches center support structure 50. Tapered edge portion 76 may be overlapped by a portion of center support structure 50 such as portion 78. Portion 78 may constrain upward motion of retractable support structures 36 along the Z-axis when device 10 is in the open state of FIG. 7. This ensures that the upward pressure applied by flexible printed circuit 74 on retractable support structure 36 does not cause wrinkles in display 14.

FIG. 8 is a top view of an illustrative torque module 34 that may be used in hinge 30 of device 10. In the example of FIG. 8, hinge module 34 includes gears 86 coupled between linkages 38. Torque module 34 also includes two sets of springs 80. A first set of springs 80-1 may be located on a first side of gears 86, and a second set of springs 80-2 may be located on an opposing second side of gears 86. Springs 80 may surround shafts such as shafts 118 that engage with cams such as cams 80-2, 84-2, and 84-3 to produce rotational torque in device 10. A first cam 84-1 may be interposed between springs 80-1 and gears 86. Springs 80-2 may be interposed between second cam 84-2 and third cam 84-3. Rotational torque may be generated by springs 80-1 pushing cam 84-1 in direction 104, by springs 80-2 pushing cam 84-2 in direction 106, and by springs 80-2 pushing cam 84-3 in direction 108. The additional torque provided by the second set of springs 80-2 and the additional cam 84-3 may be beneficial in narrow product designs that can only accommodate a certain number of torque modules 34 (e.g., two torque modules 34). If desired, cams 84-1, 84-2, and 84-3 may be formed from ceramic or other suitable material.

Clips such as clips 82 may be located on the ends of shafts 118 that pass through springs 80. If desired, the torque of module 34 may be adjusted (e.g., tuned for an individual device 10) by selecting a clip 82 with the appropriate thickness. Thicker clips 82 may be selected to increase the torque of module 34, or thinner clips 82 may be selected to decrease the torque of module 34. Arrangements in which friction plates are incorporated into torque module 34 to increase torque may also be used.

FIG. 9 is a perspective view of another illustrative torque module 34 that may be used in hinge 30 of device 10. In the example of FIG. 9, torque module 34 includes gears 86 coupled between linkages 38. Torque module 34 also includes one sets of springs 80. Springs 80 may surround shafts such as shafts 118 that engage with cams such as cams 84-1 and 84-2 to produce rotational torque in device 10. A first cam 84-1 may be interposed between springs 80 and gears 86. Gears 86 and linkages 38 may be interposed between cam 84-1 and cam 84-2. Rotational torque may be generated by springs 80 pushing shafts 118 in direction 116, which in turn pushes cam 84-2 in direction 116. Springs 80 also push cam 84-1 in direction 90 to generate additional torque. If desired, cams 84-1 and 84-2 may be formed from ceramic or other suitable material.

In the example of FIG. 9, additional torque is provided by supplemental springs 88. Each torque module 34 may include a first spring 88 located on one side of bend axis 28 and a second spring 88 located on the opposing side of bend axis 28. Springs 88 may be laterally offset from bend axis 28 by distance D, where housing space may be better able to accommodate supplemental springs 88. Each spring 88 may be coupled to a slider such as slider 120. Spring 88 may push slider 120 in direction 90 against linkage 38, which in turn pushes linkage 38 inwards towards bend axis 28 in directions 92 to produce additional torque when device 10 is open at intermediate angles.

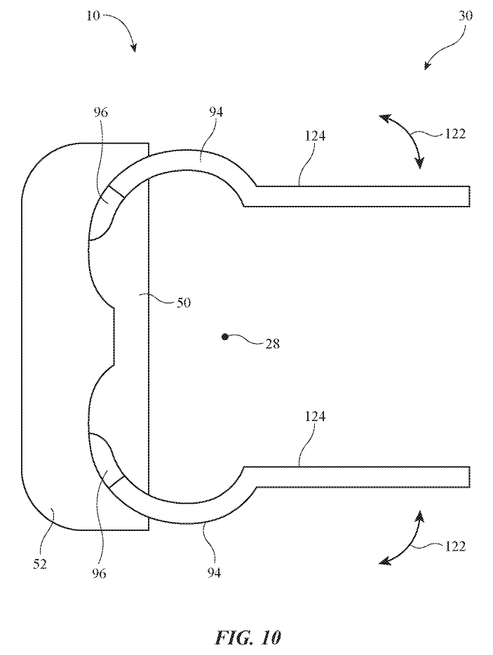

FIG. 10 is a side view of a portion of device 10 showing additional linkages that may be included in hinge 30. As shown in FIG. 10, hinge 30 may include linkages such as linkages 124. Linkages 124 may each be coupled to a respective portion of display 14. A first linkage 124 may be located on a first side of bend axis 28 and may be coupled to a first portion of display 14, and a second linkage 124 may be located on a second side of bend axis 28 and may be coupled to a second portion of display 14. Linkages 124 (sometimes referred to as swing arms) may be configured to rotate relative to one another in directions 122 as device 10 is opened and closed. Linkages 124 may move within recesses or other openings such as slots 96 behind center support structure 50.

In some arrangements, portions 94 that slide within slots 96 may have circular curvature such that linkages 124 rotate about fixed rotational axes. In other arrangements, the curvature of portions 94 that slide within slots 96 may be non-circular such that linkages 124 rotate about virtual rotational axes. For example, portions 94 may have oval curvature, elliptical curvature, or other suitable non-circular curvature. These types of shapes may help provide additional clearance between display 14 and hinge 30 (e.g., center support structure 50 of hinge 30) when device 10 is in the closed state.

Device 10 may be operated in a system that uses personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

What is claimed is:

1. An electronic device, comprising:
a flexible display having first and second portions configured to fold relative to one another along a bend axis;
a housing having first and second housing portions coupled by a hinge that overlaps the bend axis; and
first and second retractable support structures located on opposing sides of the bend axis, wherein the first and second retractable support structures are movable between a first position in which the first and second retractable support structures support a backside of the flexible display and a second position in which the first and second retractable support structures are retracted within the housing, and wherein the first and second retractable support structures are located in the first position when an angle between the first and second portions is 135°.

2. The electronic device defined in claim 1 further comprising a center support structure that overlaps and extends parallel to the bend axis, wherein the center support structure is configured to constrain motion of the first and second retractable support structures when the first and second retractable support structures are in the first position.

3. The electronic device defined in claim 2 wherein the center support structure comprises a recess that receives a portion of the first retractable support structure when the first and second retractable support structures are in the first position.

4. The electronic device defined in claim 2 wherein the first and second retractable support structures each have a tapered tip that extends under a portion of the center support structure when the first and second retractable support structures are in the first position.

5. The electronic device defined in claim 4 further comprising a flexible printed circuit that extends through the hinge and across the bend axis, wherein the flexible printed circuit pushes the tapered tip against the portion of the center support structure.

6. The electronic device defined in claim 1 further comprising a torque module in the hinge that is coupled between first and second linkages, wherein the first and second linkages have respective first and second pins configured to slide within respective slots in the first and second retractable support structures.

7. The electronic device defined in claim 6 wherein the slots each have first and second portions and wherein the second portion has a greater radius of curvature than the first portion.

8. The electronic device defined in claim 1 further comprising a torque module in the hinge, wherein the torque module comprises:
first and second sets of springs; and
first, second, and third cams, wherein the first set of springs pushes against the first cam and the second set of springs pushes against the second and third cams.

9. The electronic device defined in claim 1 further comprising a torque module in the hinge, wherein the torque module is coupled between first and second linkages and comprises:
a cam;
a set of springs that overlaps the bend axis and that pushes against the cam; and
first and second supplemental springs on opposing sides of the bend axis, wherein the first and second supplemental springs are configured to push against the first and second linkages, respectively.

10. The electronic device defined in claim 1 further comprising:
a center support structure that overlaps and extends parallel to the bend axis; and
first and second linkages on opposing sides of the center support structure, wherein the first and second linkages each have a portion with non-circular curvature that slides within a slot under the center support structure.

11. An electronic device, comprising:
a flexible display configured to fold along a bend axis;
first and second housing portions coupled by a hinge that overlaps the bend axis; and
a torque module in the hinge, wherein the torque module comprises:
first and second sets of springs; and
first, second, and third cams, wherein the first set of springs pushes against the first cam and the second set of springs pushes against the second and third cams.

12. The electronic device defined in claim 11 further comprising:
first and second retractable support structures on opposing sides of the bend axis; and
first and second linkages coupled to the torque module, wherein the first linkage has a first pin that retracts the first retractable support structure and the second linkage has a second pin that retracts the second retractable support structure.

13. The electronic device defined in claim 12 wherein the first and second pins slide within respective first and second slots in the first and second retractable support structures, wherein the first and second slots each have first and second portions, and wherein the second portion has a greater radius of curvature than the first portion.

14. The electronic device defined in claim 12 further comprising a center support structure located between the first and second retractable support structures, wherein the center support structure is configured to constrain motion of the first and second retractable support structures when the flexible display is unfolded.

15. The electronic device defined in claim 14 further comprising third and fourth linkages that each have a portion with non-circular curvature that slides within a slot under the center support structure.

16. An electronic device, comprising:
a flexible display having first and second portions configured to fold relative to one another along a bend axis;
a housing having first and second housing portions coupled by a hinge that overlaps the bend axis;
first and second retractable support structures located on opposing sides of the bend axis, wherein the first and second retractable support structures are movable between a first position in which the first and second retractable support structures support a backside of the flexible display and a second position in which the first and second retractable support structures are retracted within the housing; and
a center support structure overlapping the bend axis and located between the first and second retractable support structures, wherein the center support structure is configured to constrain motion of the first and second retractable support structures when the first and second retractable support structures are in the first position.

17. The electronic device defined in claim 16 wherein the first and second retractable support structures are configured to transition from the first position to the second position when an angle between the first and second portions drops below a threshold angle and wherein the threshold angle is less than 135°.

18. The electronic device defined in claim 16 wherein the center support structure comprises a recess that receives a portion of the first retractable support structure when the first and second retractable support structures are in the first position.

19. The electronic device defined in claim 16 further comprising a torque module in the hinge, wherein the torque module is coupled between first and second linkages and comprises:
first and second sets of springs; and
first, second, and third cams, wherein the first set of springs pushes against the first cam and the second set of springs pushes against the second and third cams.

20. The electronic device defined in claim 19 wherein the first and second linkages comprise respective first and second pins that slide within respective slots in the first and second retractable support structures.
